(19) United States
(12) Patent Application Publication
(10) Pub. No.: US 2025/0085347 A1
(43) Pub. Date: Mar. 13, 2025

(54) AUTOMATED TEST SYSTEM AND METHOD THEREOF

(71) Applicant: Wistron NeWeb Corporation, Hsinchu (TW)

(72) Inventors: Fang-Ching CHEN, Hsinchu (TW); Yung-Cheng LAI, Hsinchu (TW)

(21) Appl. No.: 18/635,423

(22) Filed: Apr. 15, 2024

(30) Foreign Application Priority Data
Sep. 8, 2023 (TW) 112134340

(51) Int. Cl. G01R 31/319

(52) U.S. Cl. CPC G01R 31/31907; G01R 31/3191

(57) ABSTRACT

An automated test system includes a plurality of modules and a plurality of basic functions executed by them. An initial setting basic function obtains a test setup file corresponding to a device under test from a test station, and reads a device basic information from the test setup file. A pre-test basic function resets the test setup file from the previous testing. A test initializing basic function confirms whether the device under test is applied to a test item of the test station according to the device basic information, and initializes a test data corresponding to the device under test according to the test item. The test station tests the device under test based on the test data to generate a test result. A post-test basic function uploads the test result to a central server, and confirms whether to receive an upload status from the central server.

### RELATED APPLICATIONS

This application claims priority to Taiwan Application Serial Number 112134340, filed Sep. 8, 2023, which is herein incorporated by reference.

### BACKGROUND

### Technical Field

The present disclosure relates to an automated test system and a method thereof. More particularly, the present disclosure relates to an automated test system and a method thereof that have standardized basic functions and can support various test projects.

### Description of Related Art

Currently, the number of programs that need to be maintained for a project that performs a plurality of tests on a product is generally proportional to the number of test stations. For example, if a project includes 7 test stations, the program code of the project has 7 source codes. During the product production process, if rework or sorting is required, project staffs/system engineers must derive other source code to be responsible for rework or sorting. Simultaneously, the project staffs also need to write the various test steps and their sequencing by themselves. Since the code of each of the test stations is developed and maintained separately, the same code cannot be shared between different test stations, resulting in increased development costs and delays in the project's development schedule, and causing the maintenance and handover of the project too complex in the future.

It can be seen that there is a lack of a test system and a method thereof on the market that can be applied to standardized testing procedures at different stations and simultaneously provide the test procedures required by each of the stations, and are indeed highly anticipated by the public and become the goal and the direction of relevant industry efforts.

### SUMMARY

According to one aspect of the present disclosure, an automated test system is configured to provide a test platform to perform a plurality of tests on a device under test, and the test platform includes a plurality of stations. The automated test system includes an initial setting module, a pre-test module, a test module and a post-test module. The initial setting module is configured to execute an initial setting basic function. The initial setting basic function obtains a test setup file corresponding to the device under test from one of the stations, and reads a device basic information from the test setup file and sets a platform setting data according to the device basic information. The pre-test module is configured to execute a pre-test basic function. The pre-test basic function resets the test setup file from a previous testing. The test module is configured to execute a test initializing basic function. The test initializing basic function confirms whether the device under test is applied to a test item of the one of the stations according to the device basic information and initializes a test data corresponding to the device under test according to the test item, and the one of the stations tests the device under test based on the test data to generate a test result. The post-test module is configured to execute a post-test basic function. The post-test basic function uploads the test result to a central server, and confirms whether to receive an upload status from the central server.

According to another aspect of the present disclosure, an automated test system is configured to provide a test platform to perform a plurality of tests on a device under test, and the test platform includes a plurality of stations. The automated test system includes an initial setting module, a pre-test module, a test module and a post-test module. The initial setting module is configured to execute an initial setting basic function and an initial setting station function in sequence. The initial setting basic function obtains a test setup file corresponding to the device under test from one of the stations, and reads a device basic information from the test setup file and sets a platform setting data according to the device basic information. The initial setting station function sets an operating mode of a fixture and turns on the fixture. The pre-test module is configured to execute a pre-test basic function and a pre-test station function. The pre-test basic function resets the test setup file from a previous testing. The pre-test station function confirms whether a device serial number of the device under test complies with a serial number rule, and confirms whether the device under test is in a retest state according to the device serial number. The test module is configured to execute a test initializing station function, a test initializing basic function and a test function in sequence. The test initializing station function resets a program parameter and turns off the fixture. The test initializing basic function confirms whether the device under test is applied to a test item of the one of the stations according to the device basic information, and initializes a test data corresponding to the device under test according to the test item. The test function tests the device under test based on the test data and generates a test result. The post-test module is configured to execute a post-test station function and a post-test basic function in sequence. The post-test station function turns on the fixture. The post-test basic function uploads the test result to a central server and confirms whether to receive an upload status from the central server. The one of the stations overwrites the initial setting basic function, the pre-test basic function, the test initializing basic function and the post-test basic function according to the test item to generate the initial setting station function, the pre-test station function, the test initializing station function and the post-test station function.

According to yet another aspect of the present disclosure, an automated test method is configured to provide a test platform to perform a plurality of tests on a device under test, and the test platform includes a plurality of stations. The automated test method includes performing an initial setting step, a pre-test step, a testing step and a post-test step. The initial setting step includes configuring an initial setting module to execute an initial setting basic function and an initial setting station function in sequence. The initial setting basic function obtains a test setup file corresponding to the device under test from one of the stations, and reads a device basic information from the test setup file and sets a platform setting data according to the device basic information. The initial setting station function sets an operating mode of a fixture and turns on the fixture. The pre-test step includes configuring a pre-test module to execute a pre-test basic function and a pre-test station function. The pre-test basic function resets the test setup file from a previous testing. The pre-test station function confirms whether a device serial number of the device under test complies with a serial number rule, and confirms whether the device under test is in a retest state according to the device serial number. The testing step includes configuring a test module to execute a test initializing station function, a test initializing basic function and a test function in sequence. The test initializing station function resets a program parameter and turns off the fixture. The test initializing basic function confirms whether the device under test is applied to a test item of the one of the stations according to the device basic information, and initializes a test data corresponding to the device under test according to the test item. The test function tests the device under test based on the test data and generates a test result. The post-test step includes configuring a post-test module to execute a post-test station function and a post-test basic function in sequence. The post-test station function turns on the fixture. The post-test basic function uploads the test result to a central server and confirms whether to receive an upload status from the central server. The one of the stations overwrites the initial setting basic function, the pre-test basic function, the test initializing basic function and the post-test basic function according to the test item to generate the initial setting station function, the pre-test station function, the test initializing station function and the post-test station function.

### BRIEF DESCRIPTION OF THE DRAWINGS

The present disclosure can be more fully understood by reading the following detailed description of the embodiment, with reference made to the accompanying drawings as follows:

FIG. 1 shows a schematic view of an automated test system according to a first example of a first embodiment of the present disclosure.

FIG. 2 shows a schematic view of an automated test system according to a second example of the first embodiment of the present disclosure.

FIG. 3 shows a flow chart of an automated test method according to a second embodiment of the present disclosure.

### DETAILED DESCRIPTION

The embodiment will be described with the drawings. For clarity, some practical details will be described below. However, it should be noted that the present disclosure should not be limited by the practical details, that is, in some embodiment, the practical details is unnecessary. In addition, for simplifying the drawings, some conventional structures and elements will be simply illustrated, and repeated elements may be represented by the same labels.

It will be understood that when an element (or device) is referred to as be “connected” to another element, it can be directly connected to the other element, or it can be indirectly connected to the other element, that is, intervening elements may be present. In contrast, when an element is referred to as be “directly connected to” another element, there are no intervening elements present. In addition, the terms first, second, third, etc. are used herein to describe various elements or components, these elements or components should not be limited by these terms. Consequently, a first element or component discussed below could be termed a second element or component.

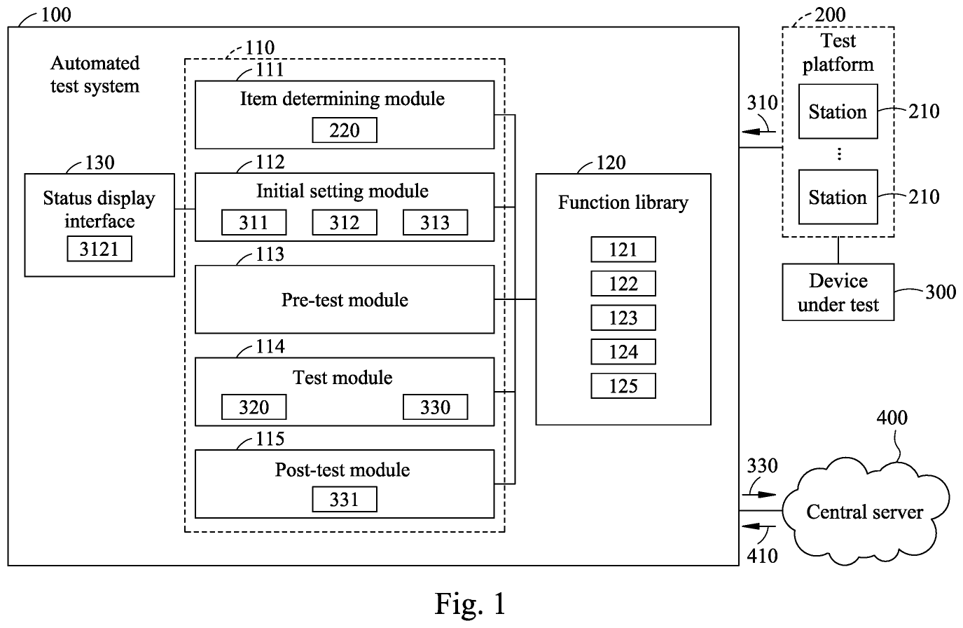

Please refer to FIG. 1. FIG. 1 shows a schematic view of an automated test system 100 according to a first example of a first embodiment of the present disclosure. In FIG. 1, the automated test system 100 is configured to provide a test platform 200 to perform a plurality of tests on a device under test (DUT) 300. The automated test system 100 can be stored in a cloud server. The test platform 200 includes a plurality of stations 210 for testing a plurality of specific functions, and each of the stations 210 can be signally connected to the cloud server through a network and download the automated test system 100 from the cloud server to test the DUT 300.

The automated test system 100 includes a test schedule 110 and a function library 120. The test schedule 110 is configured with an item determining module 111, an initial setting module 112, a pre-test module 113, a test module 114 and a post-test module 115. Each of the aforementioned modules can be a system software and signally connected to the function library 120, and each of the aforementioned modules can be run by a processor within each of the stations 210. The function library 120 stores a plurality of basic functions, and the basic functions can include an item determining basic function 121, an initial setting basic function 122, a pre-test basic function 123, a test initializing basic function 124 and a post-test basic function 125.

The item determining module 111 is configured to execute the item determining basic function 121. The item determining basic function 121 determines whether a test item of one of the stations 210 includes a robot arm test. The initial setting module 112 is configured to execute the initial setting basic function 122. The initial setting basic function 122 obtains a test setup file 310 corresponding to the DUT 300 from the one of the stations 210, and reads a device basic information 311 from the test setup file 310 and sets a platform setting data 312 according to the device basic information 311. The pre-test module 113 is configured to execute the pre-test basic function 123. The pre-test basic function 123 resets the test setup file 310 of the one of the stations 210 from the previous testing. The test module 114 is configured to execute the test initializing basic function 124. The test initializing basic function 124 confirms whether the DUT 300 is applied to the test item of the one of the stations 210 according to the device basic information 311, and initializes a test data 320 corresponding to the DUT 300 according to the test item. The one of the stations 210 stores a test function, and executes the test function through the test module 114 to test the DUT 300 based on the test data 320 to generate a test result 330. The post-test module 115 is configured to execute the post-test basic function 125. The post-test basic function 125 uploads the test result 330 to a central server 400, and confirms whether to receive an upload status 410 from the central server 400.

Therefore, the automated test system 100 of the present disclosure standardizes the basic functions required for the test item of each of the stations 210 into the item determining basic function 121, the initial setting basic function 122, the pre-test basic function 123, the test initializing basic function 124 and the post-test basic function 125 for all of the stations 210 to use. Thus, during product testing, project staffs/system engineers do not need to spend time writing the program code for the basic test process, they only need to implement the test function of the test item related to the station 210, thereby saving test development costs and reducing development time.

In detail, the DUT 300 can be an electronic device, and the electronic device can include a printed circuit board assembly (PCBA). The one of the stations 210 can be a PCBA station, and its main test items include program burning, circuit testing, functional testing, fatigue testing, aging testing and harsh environment testing, and the corresponding test functions are imported into a robot arm and a fixture in the PCBA station. In addition, the stations 210 of the present disclosure can also be, but are not limited to a radio frequency (RF) station, a throughput station, a yield station and a controller configuration tool (CCT) station. The basic functions executed by each module in the test schedule 110 are described in more detail with the drawings and the embodiments by using the PCBA station as an example below.

In the item determining basic function 121, in response to determine that the test item includes the robot arm test (i.e., when the test item uses a robot control system (RCS)), the item determining basic function 121 initializes an operating parameter 220 of the robot arm test, and initializes RCS related settings and registers with a RCS server.

In the initial setting basic function 122, the device basic information 311 read from the test setup file 310 can include a device name, a device model, a device serial number and a device test log corresponding to the DUT 300. The initial setting basic function 122 can also read a station name corresponding to the PCBA station from the test setup file 310, and sets a variable regarding how to obtain a device identifier 313. The variable includes the following two obtaining methods. One is to obtain the device identifier 313 from the DUT 300, and the other is to obtain the device identifier 313 by manually brushing a barcode.

The platform setting data 312 includes a status display configuration 3121 corresponding to the test item and a server transmission configuration corresponding to the central server 400, and the central server 400 can be a shop floor control system (SFCS) server. The automated test system 100 can further include a status display interface 130. The status display interface 130 is signally connected to the initial setting module 112 and is configured to display the status display configuration 3121. In detail, the initial setting basic function 122 can set the status display configuration 3121 according to the device basic information 311 and initialize the server transmission configuration, and the server transmission configuration includes a server address. Furthermore, the initial setting module 112 executes the initial setting basic function 122. The initial setting basic function 122 can enable the automated test system 100 downloaded to the station 210 to be signally connected to the central server 400 through the server address of the server transmission configuration, and obtains a device part number of the DUT 300 from the central server 400.

In pre-test basic function 123, the pre-test basic function 123 resets/clears a test failure record 331 of the test setup file 310 from the previous testing, and the test failure record 331 can include a test failure item and a failed device serial number.

In the test initializing basic function 124, the test initializing basic function 124 determines whether the test item of the PCBA station is a golden sample test, and confirms whether the DUT 300 can be tested at the PCBA station according to the device serial number of the device basic information 311. From the above, it can be seen that the main test item of the PCBA station do not include the golden sample test, so the test initializing basic function 124 determines that the test item in the PCBA station are not the golden sample test. After confirming that the DUT 300 can be tested at the PCBA station, the test initializing basic function 124 initializes the test data 320 corresponding to the DUT 300 according to the test item. The test data 320 can include a fixture number of the fixture of the PCBA station and the server address of the central server 400. Different from the initial setting basic function 122 that obtains the device part number corresponding to the DUT 300 from the central server 400, the test initializing basic function 124 can directly obtain the device part number corresponding to the DUT 300 according to the device serial number of the device basic information 311. Moreover, the test initializing basic function 124 can integrate the server address of the test data 320, the device serial number, the device part number and the device name of the device basic information 311, and the station name corresponding to the PCBA station into a test basic data for station staff to review. It should be noted that when the PCBA station changes the test item or the DUT 300, the pre-test basic function 123 resets the test basic data in the previous testing.

In the post-test basic function 125, the test result 330 can be divided into the following three results: a test pass, a test failure or a retest. After the test in the PCBA station is completed, the post-test basic function 125 determines whether the test result 330 is the test failure. In response to determine that the test result 330 is the test failure, the post-test basic function 125 generates a test failure record 331 according to the test result 330, and the test failure record 331 lists a test failure item and a failed device serial number. In addition, the post-test basic function 125 generates the device test log of the current test, and uploads the device test log to the central server 400, a file server or other data management systems.

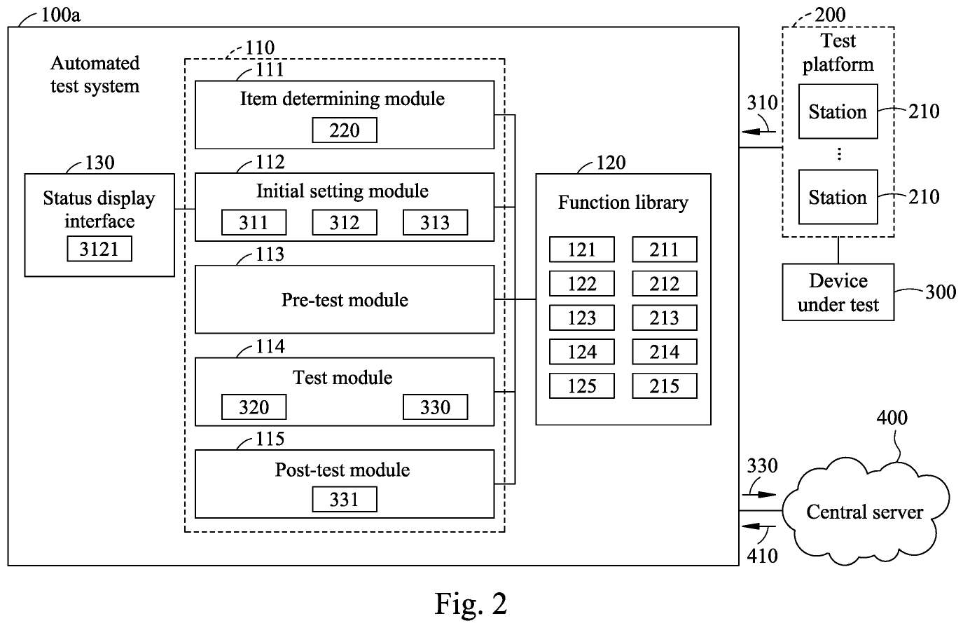

Please refer to FIG. 2. FIG. 2 shows a schematic view of an automated test system 100a according to a second example of the first embodiment of the present disclosure. The automated test system 100a includes the test schedule 110, the function library 120 and the status display interface 130. Different from the first example, the function library 120 of the automated test system 100a can further store a test function 211 and a plurality of station functions, and the station functions can include an initial setting station function 212, a pre-test station function 213, a test initializing station function 214 and a post-test station function 215.

Specifically, each of the stations 210 includes a processor, which can be a digital signal processor (DSP), a micro processing unit (MPU), or a central processing unit (CPU) or other electronic processors. The processor of each of the stations 210 creates the test function 211 according to its own test item. After downloading the automated test system 100a from the cloud server, the processor of each of the stations 210 can respectively overwrite the initial setting basic function 122, the pre-test basic function 123, the test initializing basic function 124 and the post-test basic function 125 stored in the function library 120 according to its own test item to generate the initial setting station function 212, the pre-test station function 213, the test initializing station function 214 and the post-test station function 215, and then stores the test function 211 and the aforementioned station functions in the function library 120 for the item determining module 111, the initial setting module 112, the pre-test module 113, the test module 114 and the post-test module 115 of the test schedule 110 to use (that is, for the processor of each of the station 210 to run). The operations of the test function 211 and the aforementioned station functions are described in more detail below. The basic functions stored in the function library 120 are the same as those in the first embodiment, and not be described again herein.

The initial setting module 112 is configured to execute the initial setting basic function 122 and the initial setting station function 212 in sequence. The initial setting station function 212 sets an operating mode of the fixture and turns on the fixture, so that the robot arm can place the DUT 300 in the fixture. The pre-test module 113 is configured to execute the pre-test basic function 123 and the pre-test station function 213. The pre-test station function 213 confirms whether the device serial number of the DUT 300 complies with a serial number rule, and confirms whether the DUT 300 is in a retest state according to the device serial number. The test module 114 is configured to execute the test initializing station function 214, the test initializing basic function 124 and the test function 211 in sequence. The test initializing station function 214 resets a program parameter of the test function 211 (that is, relevant parameters in the previous testing, such as a device serial number of the previous device under test, or a test data that needs to be written to the previous device under test), and turns off the fixture. The test function 211 tests the DUT 300 based on the test data 320 to generate the test result 330. The post-test module 115 is configured to execute the post-test station function 215 and the post-test basic function 125 in sequence. The post-test station function 215 turns on the fixture, so that the robot arm can take out the DUT 300 from the fixture.

Therefore, the automated test system 100a of the present disclosure can not only integrate the basic functions required for testing at the stations 210 different from each other into the initial setting basic function 122, the pre-test basic function 123, the test initializing basic function 124 and the post-test basic function 125 for all of the stations 210 to use, but also overwrite the aforementioned basic functions as the initial setting station function 212, the pre-test station function 213, the test initializing station function 214 and the post-test station function 215 for each of the stations 210 to execute the testing according to its own test item. Thus, the present disclosure can solve the problem in the prior art that the same program code cannot be shared among the stations 210 different from each other so as to greatly reduce the development time and improve the reusability of the program code. In addition, each of the stations 210 can share the aforementioned basic functions, thereby further reducing the workload of station staffs and maintenance costs, and simplifying the handover complexity.

The station functions executed by each module in the test schedule 110 are described in more detail by using a RF station as an example below.

In detail, the DUT 300 can be a communication device, and the main test item of the RF station can be a RF Calibration, and the rest of the test items can be, but are not limited to transmit/receive detection, output power, adjacent channel power ratio (ACPR), channel bandwidth, spectrum density and sensitivity.

In the initial setting station function 212, the initial setting station function 212 can initialize various prompt character settings and RF parameter settings of the DUT 300.

In the pre-test station function 213, if the device identifier 313 of the DUT 300 is obtained by manually swiping the barcode, the pre-test station function 213 is not only check the serial number rule, but also determines whether the device serial number complies with a golden special serial number rule.

In the test initializing station function 214, the test initializing station function 214 turns on the power supply of the DUT 300, that is, powers on the DUT 300, and obtains the device name and the corresponding media access control (MAC) address of the DUT 300 from the central server 400 through the device serial number.

In the test function 211, the test function 211 uses a golden sample to calibrate the DUT 300. If the calibration fails, the calibration data configured for the DUT 300 in the calibration test is cleared.

In the post-test station function 215, the post-test station function 215 turns off the power supply of the DUT 300, that is, the DUT 300 is powered off, and confirms whether there is at least one special test item (such as ACPR) that failed the test. When the at least one special test item is failed, the post-test station function 215 uploads the test result 330 to the central server 400 directly.

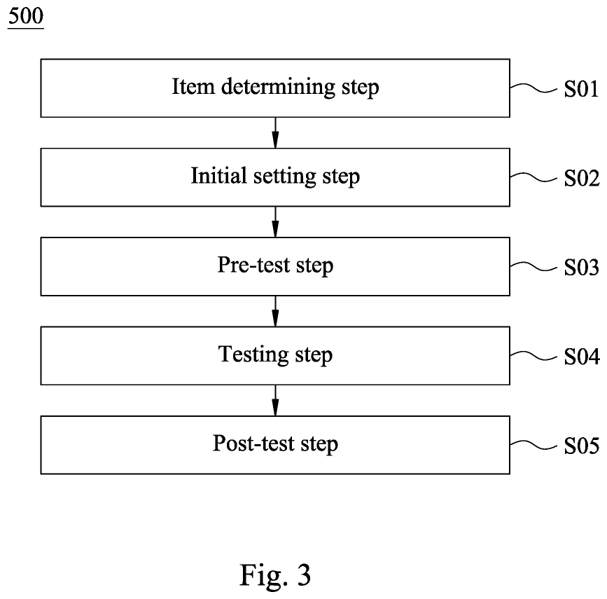

Please refer to FIGS. 2 and 3. FIG. 3 shows a flow chart of an automated test method 500 according to a second embodiment of the present disclosure. In FIGS. 2 and 3, the automated test method 500 can be applied to the automated test system 100a and configured to provide the test platform 200 to perform a plurality of tests on the DUT 300. The automated test method 500 includes performing an item determining step S01, an initial setting step S02, a pre-test step S03, a testing step S04 and a post-test step S05.

The item determining step S01 includes configuring the item determining module 111 to execute the item determining basic function 121. The item determining basic function 121 determines whether the test item includes the robot arm test. In response to determine that the test item includes the robot arm test, the item determining basic function 121 initializes the operating parameter 220 of the robot arm test, and initializes RCS related settings and registers with the RCS server.

The initial setting step S02 includes configuring the initial setting module 112 to execute the initial setting basic function 122 and the initial setting station function 212 in sequence. The initial setting basic function 122 obtains the test setup file 310 corresponding to the DUT 300 from one of the stations 210, and reads the device basic information 311 from the test setup file 310 and sets the platform setting data 312 according to the device basic information 311. The initial setting station function 212 sets the operating mode of the fixture of the one of the stations 210 and turns on the fixture.

The pre-test step S03 includes configuring the pre-test module 113 to execute the pre-test basic function 123 and the pre-test station function 213. The pre-test basic function 123 resets the test setup file 310 of the one of the stations 210 from the previous testing. The pre-test station function 213 confirms whether the device serial number of the DUT 300 complies with the serial number rule, and confirms whether the DUT 300 is in the retest state according to the device serial number.

The testing step S04 includes configuring the test module 114 to execute the test initializing station function 214, the test initializing basic function 124 and the test function 211 in sequence. The test initializing station function 214 resets the program parameter in the test function 211 and turns off the fixture. The test initializing basic function 124 confirms whether the DUT 300 is applied to the test item of the one of the stations 210 according to the device basic information 311, and initializes the test data 320 corresponding to the DUT 300 according to the test item. The test function 211 tests the DUT 300 based on the test data 320 and generates the test result 330.

The post-test step S05 includes configuring the post-test module 115 to execute the post-test station function 215 and the post-test basic function 125 in sequence. The post-test station function 215 turns on the fixture. The post-test basic function 125 uploads the test result 330 to the central server 400 and confirms whether to receive the upload status 410 from the central server 400.

Each of the stations 210 can respectively overwrite the initial setting basic function 122, the pre-test basic function 123, the test initializing basic function 124 and the post-test basic function 125 according to its own test item to generate the initial setting station function 212, the pre-test station function 213, the test initializing station function 214 and the post-test station function 215. Therefore, the automated test method 500 of the present disclosure can perform standardized testing procedures and the exclusive test items of each of the station 210 on the DUT 300 through different basic functions and station functions. When rework or sorting occurs, it can greatly save development time and improve the reusability of the program code.

In view of the above, the present disclosure has the following advantages. First, through standardized multiple basic functions, the development costs in the early stages of testing is saved, and the development time is reduced. Second, by overwriting the basic functions to the station functions, the problem in the prior art that the same program code cannot be shared among the different stations can be solved, which can not only greatly reduce the development time, but also improve the reusability of the program code. Third, each of the stations can share the basic functions, thereby further reducing the workload of station staffs and maintenance costs, and simplifying the handover complexity.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. An automated test system, which is configured to provide a test platform to perform a plurality of tests on a device under test, the test platform comprising a plurality of stations, and the automated test system comprising:
an initial setting module configured to execute an initial setting basic function, wherein the initial setting basic function obtains a test setup file corresponding to the device under test from one of the stations, and reads a device basic information from the test setup file and sets a platform setting data according to the device basic information;
a pre-test module configured to execute a pre-test basic function, wherein the pre-test basic function resets the test setup file from a previous testing;
a test module configured to execute a test initializing basic function, wherein the test initializing basic function confirms whether the device under test is applied to a test item of the one of the stations according to the device basic information and initializes a test data corresponding to the device under test according to the test item, and the one of the stations tests the device under test based on the test data to generate a test result; and
a post-test module configured to execute a post-test basic function, wherein the post-test basic function uploads the test result to a central server, and confirms whether to receive an upload status from the central server.

2. The automated test system of claim 1, further comprising:
an item determining module configured to execute an item determining basic function, wherein the item determining basic function determines whether the test item comprises a robot arm test;
wherein in response to determine that the test item comprises the robot arm test, the item determining basic function initializes an operating parameter of the robot arm test.

3. The automated test system of claim 2, further comprising:
a function library signally connected to the item determining module, the initial setting module, the pre-test module, the test module and the post-test module, and storing a plurality of basic functions;
wherein the basic functions comprise the item determining basic function, the initial setting basic function, the pre-test basic function, the test initializing basic function and the post-test basic function.

4. The automated test system of claim 1, wherein the initial setting basic function reads a station name corresponding to the one of the stations from the test setup file and obtains a device identifier from the device under test, and the device basic information comprises a device name, a device model, a device serial number and a device test log corresponding to the device under test.

5. The automated test system of claim 1, wherein the platform setting data comprises a status display configuration corresponding to the test item and a server transmission configuration corresponding to the central server, and the automated test system further comprises:
a status display interface signally connected to the initial setting module and configured to display the status display configuration;
wherein the initial setting basic function sets the status display configuration according to the device basic information and initializes the server transmission configuration, and obtains a device part number of the device under test from the central server through the server transmission configuration.

6. The automated test system of claim 1, wherein the pre-test basic function resets a test failure record of the test setup file from the previous testing, and the test failure record comprises a test failure item and a failed device serial number.

7. The automated test system of claim 1, wherein the test data comprises a fixture number and a server address, and the test initializing basic function obtains a device part number corresponding to the device under test according to a device serial number of the device basic information, and integrates the server address of the test data, the device serial number of the device basic information, the device part number and a device name into a test basic data.

8. The automated test system of claim 1, wherein the post-test basic function determines whether the test result is a test failure, and in response to determine that the test result is the test failure, the post-test basic function generates a test failure record according to the test result.

9. An automated test system, which is configured to provide a test platform to perform a plurality of tests on a device under test, the test platform comprising a plurality of stations, and the automated test system comprising:
an initial setting module configured to execute an initial setting basic function and an initial setting station function in sequence, wherein the initial setting basic function obtains a test setup file corresponding to the device under test from one of the stations and reads a device basic information from the test setup file and sets a platform setting data according to the device basic information, and the initial setting station function sets an operating mode of a fixture and turns on the fixture;
a pre-test module configured to execute a pre-test basic function and a pre-test station function, wherein the pre-test basic function resets the test setup file from a previous testing, and the pre-test station function confirms whether a device serial number of the device under test complies with a serial number rule and confirms whether the device under test is in a retest state according to the device serial number;
a test module configured to execute a test initializing station function, a test initializing basic function and a test function in sequence, wherein the test initializing station function resets a program parameter and turns off the fixture, the test initializing basic function confirms whether the device under test is applied to a test item of the one of the stations according to the device basic information and initializes a test data corresponding to the device under test according to the test item, and the test function tests the device under test based on the test data and generates a test result; and
a post-test module configured to execute a post-test station function and a post-test basic function in sequence, wherein the post-test station function turns on the fixture, and the post-test basic function uploads the test result to a central server and confirms whether to receive an upload status from the central server;
wherein the one of the stations overwrites the initial setting basic function, the pre-test basic function, the test initializing basic function and the post-test basic function according to the test item to generate the initial setting station function, the pre-test station function, the test initializing station function and the post-test station function.

10. The automated test system of claim 9, further comprising:
an item determining module configured to execute an item determining basic function, wherein the item determining basic function determines whether the test item comprises a robot arm test;
wherein in response to determine that the test item comprises the robot arm test, the item determining basic function initializes an operating parameter of the robot arm test.

11. The automated test system of claim 10, further comprising:
a function library signally connected to the item determining module, the initial setting module, the pre-test module, the test module and the post-test module, and storing a plurality of basic functions;
wherein the basic functions comprise the item determining basic function, the initial setting basic function, the pre-test basic function, the test initializing basic function and the post-test basic function.

12. The automated test system of claim 9, wherein the initial setting basic function reads a station name corresponding to the one of the stations from the test setup file and obtains a device identifier from the device under test, and the device basic information comprises a device name, a device model, the device serial number and a device test log corresponding to the device under test.

13. The automated test system of claim 9, wherein the platform setting data comprises a status display configuration corresponding to the test item and a server transmission configuration corresponding to the central server, and the automated test system further comprises:
a status display interface signally connected to the initial setting module and configured to display the status display configuration;
wherein the initial setting basic function sets the status display configuration according to the device basic information and initializes the server transmission configuration, and obtains a device part number of the device under test from the central server through the server transmission configuration.

14. The automated test system of claim 9, wherein the pre-test basic function resets a test failure record of the test setup file from the previous testing, and the test failure record comprises a test failure item and a failed device serial number.

15. The automated test system of claim 9, wherein the test data comprises a fixture number and a server address, and the test initializing basic function obtains a device part number corresponding to the device under test according to the device serial number, and integrates the server address of the test data, the device serial number of the device basic information, the device part number and a device name into a test basic data.

16. The automated test system of claim 9, wherein the post-test basic function determines whether the test result is a test failure, and in response to determine that the test result is the test failure, the post-test basic function generates a test failure record according to the test result.

17. An automated test method, which is configured to provide a test platform to perform a plurality of tests on a device under test, the test platform comprising a plurality of stations, and the automated test method comprising:
performing an initial setting step comprising configuring an initial setting module to execute an initial setting basic function and an initial setting station function in sequence, wherein the initial setting basic function obtains a test setup file corresponding to the device under test from one of the stations and reads a device basic information from the test setup file and sets a platform setting data according to the device basic information, and the initial setting station function sets an operating mode of a fixture and turns on the fixture;
performing a pre-test step comprising configuring a pre-test module to execute a pre-test basic function and a pre-test station function, wherein the pre-test basic function resets the test setup file from a previous testing, and the pre-test station function confirms whether a device serial number of the device under test complies with a serial number rule and confirms whether the device under test is in a retest state according to the device serial number;
performing a testing step comprising configuring a test module to execute a test initializing station function, a test initializing basic function and a test function in sequence, wherein the test initializing station function resets a program parameter and turns off the fixture, the test initializing basic function confirms whether the device under test is applied to a test item of the one of the stations according to the device basic information and initializes a test data corresponding to the device under test according to the test item, and the test function tests the device under test based on the test data and generates a test result; and
performing a post-test step comprising configuring a post-test module to execute a post-test station function and a post-test basic function in sequence, wherein the post-test station function turns on the fixture, and the post-test basic function uploads the test result to a central server and confirms whether to receive an upload status from the central server;
wherein the one of the stations overwrites the initial setting basic function, the pre-test basic function, the test initializing basic function and the post-test basic function according to the test item to generate the initial setting station function, the pre-test station function, the test initializing station function and the post-test station function.

18. The automated test method of claim 17, further comprising:
performing an item determining step comprising configuring an item determining module to execute an item determining basic function, wherein the item determining basic function determines whether the test item comprises a robot arm test;
wherein in response to determine that the test item comprises the robot arm test, the item determining basic function initializes an operating parameter of the robot arm test.

19. The automated test method of claim 17, wherein the initial setting basic function reads a station name corresponding to the one of the stations from the test setup file and obtains a device identifier from the device under test, and the device basic information comprises a device name, a device model, the device serial number and a device test log corresponding to the device under test.

20. The automated test method of claim 17, wherein the platform setting data comprises a status display configuration corresponding to the test item and a server transmission configuration corresponding to the central server, and the initial setting basic function sets the status display configuration according to the device basic information and initializes the server transmission configuration, and obtains a device part number of the device under test from the central server through the server transmission configuration.

21. The automated test method of claim 17, wherein the pre-test basic function resets a test failure record of the test setup file from the previous testing, and the test failure record comprises a test failure item and a failed device serial number.

22. The automated test method of claim 17, wherein the test data comprises a fixture number and a server address, and the test initializing basic function obtains a device part number corresponding to the device under test according to the device serial number, and integrates the server address of the test data, the device serial number of the device basic information, the device part number and a device name into a test basic data.

23. The automated test method of claim 17, wherein the post-test basic function determines whether the test result is a test failure, and in response to determine that the test result is the test failure, the post-test basic function generates a test failure record according to the test result.
